(19) United States
(12) Patent Application Publication
(10) Pub. No.: US 2026/0182379 A1
(43) Pub. Date: Jun. 25, 2026

(54) INTEGRATED CIRCUIT SUBSTRATE STIFFENER

(71) Applicant: Arm Limited

(72) Inventors: Javier DeLaCruz, San Jose, CA (US); Cameron Cole Nelson, Gilbert, AZ (US)

(21) Appl. No.: 19/001,120

(22) Filed: Dec. 24, 2024

(51) Int. Cl. H01L 23/00; H01L 21/48; H01L 23/367; H01L 23/498

(52) U.S. Cl. CPC H10W 42/121; H10W 40/037; H10W 40/22; H10W 76/01; H10W 72/877; H10W 90/701; H10W 90/724; H10W 90/736

(57) ABSTRACT

An integrated circuit assembly comprises a substrate, and an integrated circuit die physically and electrically attached to the substrate. A stiffener is attached to the substrate, the stiffener comprising a planar portion and a protruding portion, the planar portion to be attached to the substrate and to be positioned approximately parallel to a planar surface of the substrate, the protruding portion to extend away from the planar portion of the stiffener.

### FIELD

The field relates to packaging integrated circuit devices, and more specifically to an integrated circuit substrate stiffener.

### BACKGROUND

Modern computerized devices process and store information in a variety of ways, including using processors that may have multiple cores and cache memory that may be associated with each of at least some of the processor cores. The processors in modern high-performance consumer electronics devices such as smart phones, tablet computers, set top boxes, and the like, may have multiple processor cores, graphics engines, artificial intelligence or neural network processors, cache memory, and a variety of other such functions on a single integrated circuit. The number of transistors on an integrated circuit therefore continues to grow, as does the power dissipated by an integrated circuit for a given process size (or device pitch size).

Such processors are often incorporated into products from handheld devices such as smartphones to large processors used in data centers, and are typically packaged or supported and protected in various ways before integration into an electronic device. Packages for integrated circuits such as these often perform several roles, from providing connection between the integrated circuit and a printed circuit board to thermal dissipation, environmental protection, and power support or regulation. Contacts on the integrated circuit may be attached to a substrate such as using flip chip, wire bond, or ball grid arrays, and the substrate may be coupled to a circuit board using a ball grid array, pin grid array, or similar connection scheme. The package may also support a heat sink or heat spreader, such as may be mounted in close thermal contact with the integrated circuit die using thermal paste or another thermal conductor. Devices such as capacitors, inductors, and the like may further be mounted to the substrate, supporting steady voltage regulation during periods of transition such as powering up or changing a performance mode of a processor core.

Some integrated circuit packages may have a variety of other features, such as metal enclosures or lids that protect the top of the integrated circuit from damage and that conduct heat to a heat sink or other thermal solution. Lids may also serve to spread heat from the integrated circuit die to a wider area in contact with a heat sink, but in some high performance environments may add too much resistance between the integrated circuit die and the thermal solution so may be omitted. Mounting the integrated circuit to the substrate often involves reflowing a solder ball array such as a flip chip ball grid array of solder balls between the integrated circuit package and the substrate, which can cause substantial warpage between the integrated circuit and the substrate such as where the coefficients of thermal expansion between the substrate and integrated circuit die are different. Some integrated circuit packages may therefore employ a stiffener, such as a metal loop attached around the perimeter of the substrate, to help the substrate resist warping as the integrated circuit package cools after solder reflow.

Larger integrated circuit dies and correspondingly larger substrates may require more robust stiffeners, and integrated circuit packages that dissipate high amounts of power or heat may further benefit from improved stiffness to prevent warpage as the packages heats and cools. Increasingly complex power demands may also involve more or larger capacitors on the integrated circuit package to support power delivery to the integrated circuit die, taking additional space on the substrate and either requiring a larger substrate or making less space available for a stiffener. For reasons such as these, a need exists for an improved stiffener for integrated circuit packages.

### BRIEF DESCRIPTION OF THE DRAWINGS

The claims provided in this application are not limited by the examples provided in the specification or drawings, but their organization and/or method of operation, together with features, and/or advantages may be best understood by reference to the examples provided in the following detailed description and in the drawings, in which:

FIG. 1 shows an example integrated circuit assembly, as may be used to practice some example embodiments.

FIG. 2 is a side view of an integrated circuit assembly having a stiffener with a perpendicular protrusion extending away from an integrated circuit die mounting surface of the substrate, consistent with an example embodiment.

FIG. 3 is a side view of an integrated circuit assembly having a stiffener with a protrusion having two bends, consistent with an example embodiment.

FIG. 4 is a side view of an integrated circuit assembly having a stiffener with a protrusion extending in two directions, consistent with an example embodiment.

FIG. 5 is a side view of an integrated circuit assembly having a stiffener with a protrusion that does not extend past the edges of a stiffener, consistent with an example embodiment.

FIG. 6 is a side view of an integrated circuit assembly having a stiffener with a standoffs for spacing and support, consistent with an example embodiment.

FIG. 7 is a chart showing deflection of various integrated circuit assemblies, consistent with an example embodiment.

FIG. 8 is a flow diagram of a method of forming an integrated circuit assembly having a stiffener with a protruding portion, consistent with an example embodiment.

FIG. 9 shows a block diagram of a general-purpose computerized system, consistent with an example embodiment.

Reference is made in the following detailed description to accompanying drawings, which form a part hereof, wherein like numerals may designate like parts throughout that are corresponding and/or analogous. The figures have not necessarily been drawn to scale, such as for simplicity and/or clarity of illustration. For example, dimensions of some aspects may be exaggerated relative to others. Other embodiments may be utilized, and structural and/or other changes may be made without departing from what is claimed. Directions and/or references, for example, such as up, down, top, bottom, and so on, may be used to facilitate discussion of drawings and are not intended to restrict application of claimed subject matter. The following detailed description therefore does not limit the claimed subject matter and/or equivalents.

### DETAILED DESCRIPTION

In the following detailed description of example embodiments, reference is made to specific example embodiments by way of drawings and illustrations. These examples are described in sufficient detail to enable those skilled in the art to practice what is described, and serve to illustrate how elements of these examples may be applied to various purposes or embodiments. Other embodiments exist, and logical, mechanical, electrical, and other changes may be made.

Features or limitations of various embodiments described herein, however important to the example embodiments in which they are incorporated, do not limit other embodiments, and any reference to the elements, operation, and application of the examples serve only to aid in understanding these example embodiments. Features or elements shown in various examples described herein can be combined in ways other than shown in the examples, and any such combinations is explicitly contemplated to be within the scope of the examples presented here. The following detailed description does not, therefore, limit the scope of what is claimed.

Many modern computing systems employ processors with multiple processing cores, such that certain tasks that can be performed in parallel can be distributed among the cores for faster execution or different tasks can be performed simultaneously by different processors. The integrated circuits upon which processor cores are formed may also contain graphics processors, such as are able to render graphical images at high speed, encode and decode various video formats, and the like. Sone processor integrated circuits also include artificial intelligence processing, such as neural network processors or the like that may be used to provide various functions such as chatbots, self-driving vehicles, and various other such functions. These increases in functionality may come at the expense of added transistor count in the integrated circuit, which may add to the integrated circuit's physical size, power consumed, and number of external connections.

As the size of integrated circuits grows, packaging the integrated circuit may become increasingly challenging. The integrated circuit die is often attached to a substrate, such as using a flip-chip ball grid array of electrical connections between the integrated circuit and the substrate, such that the substrate can provide a wider pitch for an array of electrical connections to a printed circuit board such as using a ball grid array or pin grid array. The substrate in some examples may support components such as capacitors, inductors, and the like to support power delivery to the integrated circuit. The substrate may also support a lid configured to provide protection and rigidity to the integrated circuit package assembly, but lids are often omitted in high performance devices due to the thermal impedance they may introduce between the integrated circuit die and a heat sink or other thermal solution.

The integrated circuit die is typically mounted to a substrate using a solder reflow operation in which an array of solder balls deposited on electrical contacts of at least one of the integrated circuit die and the substrate are heated to the point of melting. This allows the solder balls to form a physical and electrical link between corresponding contacts on the integrated circuit die and the substrate, and surface tension in the melted solder balls typically ensures good alignment between the integrated circuit and the substrate while the solder balls cool and form a bond. But, the coefficient of thermal expansion of an integrated circuit die and a substrate are often different, and the integrated circuit assembly may warp as the substrate and the coupled integrated circuit die cool after reflow. Support structures such as lids may help resist warping, and stiffeners such as a ring of metal that may be attached near the perimeter of the substrate to provide extra rigidity such as for large integrated circuit packages that do not have a lid coupled to the substrate.

But, the physical size of stiffener rings may be constrained by factors such as the dimensions of the edges of the substrate, the desire to mount components such as capacitors on the substrate near the integrated circuit, and space to mount a thermal solution in contact with the top of the mounted integrated circuit die. Improved stiffeners may therefore be of benefit for large substrates, or substrates where factors such as these constrain the physical size of the stiffener that may be employed.

Some examples presented herein therefore comprise stiffeners having one or more protruding features extending upward from a planar portion of a stiffener to be attached to the substrate. The protruding features in some examples may extend approximately perpendicular or normal to the planar portion of the stiffener to improve stiffness or resist deflection in the direction normal to the planar portion of the stiffener. The stiffener in various examples may comprise copper, steel, silicon carbide, aluminum silicon carbide, and/or another such material having desired stiffness, and may in further examples be work-hardened or forged to improve its stiffness. The stiffener may in various examples be configured not to extend beyond the edges of a substrate, to not interfere with a thermal solution to be mounted to the surface of the integrated circuit die, to include a standoff to maintain space between the substrate and a printed circuit board, or to accommodate other such physical constraints.

In one such example, an integrated circuit assembly comprises a substrate, and an integrated circuit die physically and electrically attached to the substrate. A stiffener is attached to the substrate and comprises a planar portion and a protruding portion, the planar portion to be attached to the substrate leaving at least a portion of the die exposed and to be positioned approximately parallel to a planar surface of the substrate, the protruding portion to extend away from the planar portion of the stiffener. In a further example, the protruding portion may extend approximately normal to the planar portion of the stiffener to provide improved stiffness or rigidity in the normal direction.

In another example, a method of forming an integrated circuit assembly comprises mounting an integrated circuit die to a substrate, and forming a stiffener comprising a planar portion and a protruding portion. The stiffener is mounted to the substrate leaving at least a portion of the die exposed, the planar portion of the stiffener mounted approximately parallel to a planar surface of the substrate, the protruding portion to extend away from the planar portion of the stiffener.

An integrated circuit assembly in another example comprises a stiffener configured to attach to a substrate carrying an integrated circuit die, the stiffener comprising a work-hardened material, the stiffener comprising a planar portion in a plane approximately parallel to a plane of the substrate when attached to the substrate leaving at least a portion of the die exposed, and a protruding portion extending away from the plane of the planar portion of the stiffener. In a further example, the work-hardened material comprises a material work-hardened by bending, forging, or drawing, or a combination thereof, at least a portion of the stiffener.

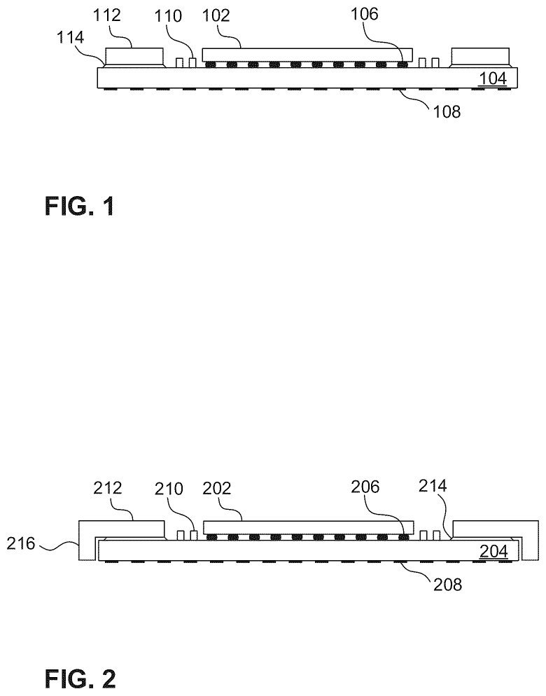

FIG. 1 shows an example integrated circuit assembly, as may be used to practice some example embodiments. Here, an integrated circuit die 102 is attached to a substrate 104, such as using solder balls 106 in a flit chip ball grid array. The substrate may be attached to a printed circuit board via contacts 108, such as using a ball grid array of solder balls, a pin grid array of pins and sockets, or another such method. One or more capacitors and/or other electrical components are shown an 110, and may be used for various purposes such as to support power delivery to the integrated circuit. A stiffener 112 is mounted to the substrate 104 using an adhesive 114 such as epoxy, and in a further example may be mounted to the substrate 104 before the integrated circuit die 102 so that it is able to provide improved stiffness to the integrated circuit assembly during solder reflow mounting the integrated circuit die to the substrate. In other examples, the stiffener may be added after mounting the integrated circuit die to the substrate, such that the stiffener provides improved stiffness to the substrate while reflowing a ball grid array of solder balls to mount the substrate to a printed circuit board and/or when the integrated circuit assembly heats up during integrated circuit operation.

The flip chip ball grid array shown at 106 and a ball grid array used to connect electrical contacts 108 to a printed circuit board may be may be known in the art as a ball grid array or BGA, and are commonly used as an electrical and physical interface between circuit components such as an integrated circuit package and a substrate, an interposer and a substrate, or the like. Ball grid arrays are often used to permanently mount devices such as microprocessors to circuit boards or substrates where a large number of contacts between the integrated circuit device and other circuitry are needed, such as where a flat package or dual in-line package are not sufficient. Further, a ball grid array interconnect typically has shorter traces between the solder balls in the array and the integrated circuit than other packages such as a flat package, potentially providing improved high speed performance. In alternate examples, the electrical contacts shown at 108 may be a grid array of pins (known as a pin grid array or PGA), which may be soldered to a circuit board or removably captured by a socket, or another type of electrical and/or physical connection arranged in an array or a grid.

Arrays of solder balls may be formed in some examples by forming metal pads and adhering solder balls to the pads on either the integrated circuit package, the substrate, or both. The arrays may be in a grid pattern, such as a square grid, diagonal grid, or other such grid pattern that is desirably uniform and repeatable or standardized, such that different entities such as integrated circuit manufacturers and product circuit board manufacturers can easily produce matching or interfacing grid arrays. Solder balls may be placed using automated equipment, and may be held in place by flux before being flowed or melted into adherence with the pads such as with a reflow oven or infrared heater. Surface tension may cause molten solder to hold an integrated circuit package in alignment with the substrate during a heating cycle, holding the integrated circuit package and substrate at a desired distance apart. When the solder balls cool, the solder balls form physical and electrical coupling between the integrated circuit and substrate.

The ball grid array as shown at 106 in FIG. 1 may be further used to mount multiple integrated circuit packages to an interposer, such as where multiple integrated circuit dies are mounted to the same substrate, but each integrated circuit die is mounted to its own interposer which is itself mounted to the substrate. The ball grid array, once reflowed to mount one layer to another, may further be filled with an underfill material filling gaps between solder balls in the ball grid array. This underfill may reduce thermal stress from heating and cooling between the integrated circuit die and the substrate such as due to differences in coefficient of thermal expansion, and may protect the integrated circuit die and the substrate from water intrusion or other contamination. In further examples, a protective package covering the top of the integrated circuit die may be employed to provide thermal conductivity to a heat sink for the integrated circuit die, and an array of external electrical contacts, and/or other such components may be employed.

The integrated circuit die 102 may in various embodiments comprise various digital analog, or mixed circuits. Digital circuit examples include one or more processor cores, graphics processors, memory, signal processors, and other digital circuits, while analog circuit examples include amplifiers, filters, analog communication circuits, and the like. Mixed signal integrated circuits may contain both digital and analog circuits on the same device, such as a wireless networking integrated circuit operable to process both analog radio waves and digital data signals to facilitate transmission and/or reception of digital data using analog radio waves. The substrate in various examples may comprise a fiberglass and resin, organic laminate, ceramic, or other suitable material, and may contain within one or more conductive layers comprising various signal, power, and other electrical interconnects coupling the flip-chip bumps to ball grid array (BGA) solder balls, Land Grid Array (LGA) contact pads, Pin Grid Array pins, or other package electrical connections.

The substrate 104 in this example may be a material such as a resin, fiberglass reinforced resin, ceramic material, or the like, and in further examples may be built up of layers having electrical traces disposed between layers of fiberglass and resin, much like a printed circuit board but often at a higher density. The substrate's layers of electrical connections may be interconnected with vias, or vertical conductors that link electrical connections on one layer of the substrate with electrical connections on another layer. The substrate may also have electrical traces or pads on its exterior surfaces, such as to provide connection points for components such as capacitors 110 and ball grid array solder ball pads 108.

Stiffener 112 may be attached to the substrate 104 using an adhesive 114 such as epoxy, and may be formed of metal, ceramic, resin, polymer, or other such material. In some embodiments, metal, ceramic, or metal-ceramic composites may be preferred for their relatively high stiffness, such as copper, steel, silicon carbide, aluminum silicon carbide, and the like. The stiffener may be configured to attach to the substrate around the edges of the substrate, both because the edges of the substrate may be the areas of greatest deflection and because the middle of the substrate may typically be occupied by integrated circuit die 102, capacitors 110, and other such components.

The stiffener 112 may also be configured in some examples not to extend beyond the edges of the substrate 104, such as to avoid interfering with neighboring components, to facilitate mounting the substrate in a socket, or the like. The substrate 112 may similarly be constrained from being positioned above the top of integrated circuit die 102, at least in areas near the integrated circuit die, so that the stiffener does not interfere with attachment of a heat sink or other thermal solution. In some such examples, the stiffener leaves at least a portion of the die exposed or revealed, and as shown in the examples presented herein, and does not completely cover the die as a typical integrated circuit package lid or heat spreader might.

Addition of a protruding stiffener element to stiffener 112 in a direction extending away from the plane of the stiffener and the substrate may improve stiffness of the stiffener. Configuration of a protruding stiffener element may depend at least in part on which constraints such as these are relevant for a particular application, such as where protruding past the edges of the stiffener, above the height of the integrated circuit die, or adding stiffness in another area may be permissible.

FIG. 2 is a side view of an integrated circuit assembly having a stiffener with a perpendicular protrusion extending away from an integrated circuit die mounting surface of the substrate, consistent with an example embodiment. Here, an integrated circuit die 202 is mounted to substrate 204 using a flip chip ball grid array (FCBGA), much as in the example of FIG. 1. Contacts 208 facilitate solder balls in a ball grid array attaching the substrate to a printed circuit board, and capacitors 210 are soldered to conductive pads and coupled to integrated circuit die 202 to support steady voltage power delivery to the integrated circuit. Stiffener 212 is attached to the substrate using adhesive 214, much as in the example of FIG. 1, but the stiffener further comprises a protruding portion 216 that protrudes or extends from the plane of stiffener 212 (or of stiffener 112 in FIG. 1).

The protruding portion 216 in this example is oriented such that its long axis is closer to the direction of possible deflection or warping of the substrate 204, which is perpendicular to its plane. Because the long axis of stiffener 112 as shown in FIG. 1 is in the same plane as the substrate 104, it may not resist warping as well as the same amount of material having a long axis nearer the direction of possible warping, or perpendicular to the plane of the substrate. The protruding portion 216 in a further example therefore may be oriented such that its long axis is approximately in the same plane as the direction of potential warping or deflection of the substrate, which in many examples may be approximately perpendicular to the plane of the substrate. Protruding portion 216 of the stiffener shown in FIG. 2 is therefore configured such that its long axis is approximately perpendicular to the plane of the substrate 204, which may provide greater resistance against substrate deflection than if the same amount of protruding material extended in the same plane as the substrate.

Although the protruding portion 216 of the stiffener is shown here as extending toward the side of the substrate opposite the integrated circuit, other examples may have a protruding portion of a stiffener protruding approximately perpendicular to the plane of the substrate extending in the same direction as the integrated circuit die 202 or in both the same and opposite directions as the side of the substrate where the integrated circuit die 202 is mounted (i.e., both up and down as shown in FIG. 2). The example of FIG. 2 also shows a protruding portion of a stiffener extending past the edge boundaries of the substrate 204, while other examples may comprise a protruding portion that does not extend past the edges of the substrate 204, or that have additional features such as standoffs ensuring proper spacing between the substrate 204 and a printed circuit board mounted via electrical contacts 208. In some examples, the cross sectional area of the stiffener as shown in FIG. 2 may include a stiffener having a planar portion as shown at 212 and a protruding portion extending away from the plane of the planar portion, such that when viewed as a cross section as in FIG. 2 the protruding portion provides enhanced stiffness through angles, bends, protrusions, or other such features relative to the plane of stiffener 212.

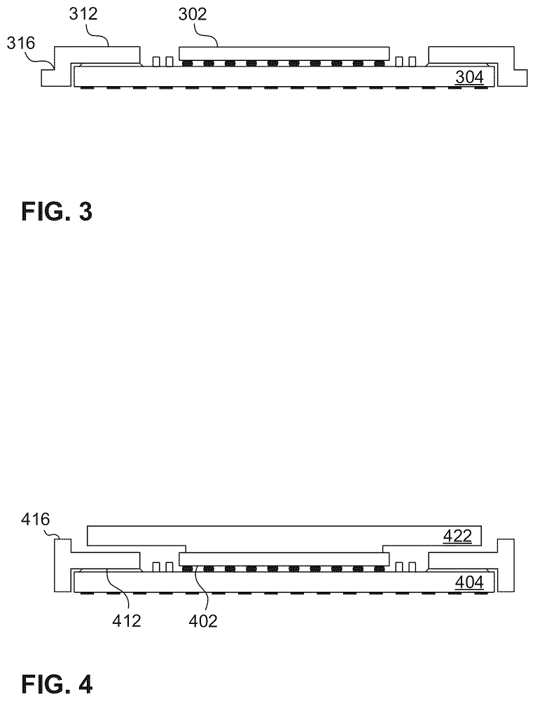

FIG. 3 is a side view of an integrated circuit assembly having a stiffener with a protrusion having two bends, consistent with an example embodiment. Here, an integrated circuit die assembly comprising an integrated circuit die 302, a substrate 304, and a stiffener 312 are configured much as in the example of FIG. 2. The stiffener in this example may comprise a sheet material that is bendable, such as sheet metal or another such material. In a more detailed example, the metal may comprise copper, steel, silicon carbide, aluminum silicon carbide, a combination thereof, or another such metal or metal alloy.

Some metal alloys may be subject to a process known as work hardening, in which deliberately changing the shape of the metal such as by bending, hammering, rolling, drawing, forging, or other such physical deformation processes may increase the stiffness or strength of the metal. In some further embodiments, significant material manipulation such as bending multiple times beyond an initial bending may improve work hardening up to a material limit, and so some work hardening processes may be repeated or involve greater deformation of the initial metal stiffener than may otherwise be necessary to achieve a desired shape. As referred to herein, “work-hardened material” means a material that is been subjected to strain hardening or cold working to increase the material's load-bearing capacity (e.g., strength or hardness) during plastic deformation.

In the example shown in FIG. 3, a flat material such as sheet metal may be bent to form the protruding portion of the stiffener, such as in the example of FIG. 3. The example shown in FIG. 3 includes an additional stiffener portion extending parallel to the plane of the stiffener, formed by making a second bend in the stiffener sheet metal material as shown at 316. Because the stiffener of FIG. 3 may be formed using two bends instead of the single bend required to form the stiffener of FIG. 2, the stiffener may be stiffer overall, both because of work hardening performed in making the second bend and because of the additional stiffener portion parallel and in line with the plane of the substrate.

In another example, the stiffener of FIG. 3 may be extruded using a die, may be forged from a metal blank or billet, or may be formed in another such process that involves work hardening the stiffener material. In alternate examples, the bend shown at 316 may be a bend at other than 90 degrees, such as a 180 degree bend that causes the part of the protrusion parallel to and in line with the substrate to instead extend perpendicular to the substrate, back away form a printed circuit board and parallel to the first part of the protrusion shown in FIG. 2.

FIG. 4 is a side view of an integrated circuit assembly having a stiffener with a protrusion extending in two directions, consistent with an example embodiment. Here, an integrated circuit die assembly comprising an integrated circuit die 402, a substrate 404, and a stiffener 412 are configured much as in the previous examples. The stiffener has a protruding portion 416 that extends away from the part of the stiffener that is parallel to a plane of the substrate 404 in both directions from the plane of the planar portion 412 of the stiffener, providing greater rigidity or stiffness in the direction of the protrusion and in the likely direction of deflection for the substrate 404.

The stiffener in this example extends beyond the edges of the stiffener 404, enabling the stiffener's protruding portion to extend across the plane of the substrate in a direction perpendicular to the plane of the substrate. The stiffener protrusion 416 in this example also extends in the opposite direction, away from the plane of the substrate and perpendicular to the plane of the substrate, providing greater rigidity or stiffness in the direction of the protrusion and in the direction of concern for deflection or warpage in the substrate 404. In a further example, the stiffener as shown in FIG. 4 may be extruded, forged, or otherwise work-hardened such as in the example of FIG. 3 to provide greater material stiffness or strength and greater resistance to deflection. The stiffener's planar portion 412 and protruding portion 416 may in some embodiments be configured to facilitate or provide space for mounting a heat sink 422 to the integrated circuit die 402, such as by not exceeding the height of the mounted integrated circuit die 402 above the substrate 404 near the integrated circuit die or in the area of the heat sink. The heat sink in various examples may comprise an air-cooled heat sink, a liquid-cooled heat sink, or any other type of heat sink configured to draw heat away from the integrated circuit die.

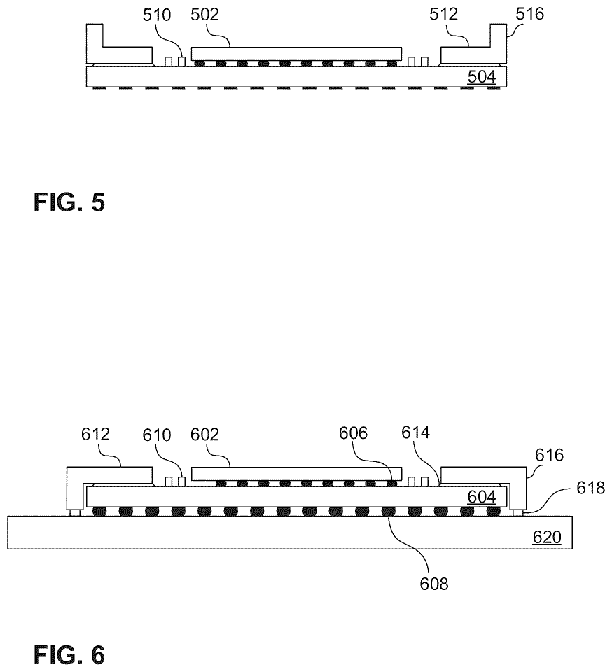

FIG. 5 is a side view of an integrated circuit assembly having a stiffener with a protrusion that does not extend past the edges of a stiffener, consistent with an example embodiment. An integrated circuit die assembly comprising an integrated circuit die 502, a substrate 504, and a stiffener 512 are configured much as in the previous examples. The stiffener has a protruding portion 516 that extends away from the part of the stiffener that is parallel to a plane of the substrate 504, providing greater rigidity or stiffness in the direction of the protrusion and in the likely direction of deflection for the substrate 504.

The stiffener 512 and the protruding portion 516 in this example do not extend past the edges of the substrate 504 in the direction of the plane of the substrate, such that the stiffener does not expand the footprint or area of the integrated circuit assembly when mounted to a printed circuit board. This facilitates more dense placement of components on the printed circuit board, and enables critical components such as large bypass capacitors to be placed closer to the integrated circuit die 502.

The example of FIG. 5 further illustrates one example stiffener configuration that may accommodate additional components such as capacitors 510 and a heat sink or other thermal interface for the integrated circuit die 502. More specifically, the height of the main body of the stiffener 512 may be configured such that it does not extend above a surface of the integrated circuit die 502, as is shown in FIG. 5, allowing a heat sink or other thermal dissipation solution to extend over both the integrated circuit die 502 and the main body of the stiffener 502. The protruding portion 516 of the stiffener is coupled to the main body 512 of the stiffener at a portion of the stiffener body farthest from the integrated circuit die 502, leaving room for a relatively large heat sink or other thermal solution. The stiffener in a further example may be configured to contact or engage with the heat sink or thermal solution, such as to support the thermal solution or to use the thermal solution to provide additional rigidity.

The stiffener 512 and protruding portion 516 of FIG. 5 may be formed using a process that work hardens the material as in previous examples presented herein, such as by bending sheet metal, or by drawing or forging metal to form the stiffener and protruding portion. The stiffener may also be configured to allow space for electrical components such as bypass capacitors 510 or the like to be placed on the substrate physically near the integrated circuit die, facilitating low impedance and rapid signal connection to the integrated circuit die.

FIG. 6 is a side view of an integrated circuit assembly having a stiffener with a standoffs for spacing and support, consistent with an example embodiment. The integrated circuit die assembly again comprises an integrated circuit die 602, a substrate 604, and a stiffener 612, configured much as in the previous examples. The stiffener has a main portion that is parallel to a plane of the substrate 604, and a protruding portion 616 that extends away from the plane of the substrate at approximately a right angle toward a printed circuit board 620. The integrated circuit assembly's substrate 604 is in this example mounted to the printed circuit board 604 using a ball grid array of electrical contacts 608, and employs one or more standoffs 618 coupled to the stiffener or integrated into the stiffener to ensure a desired spacing or position is maintained.

In some embodiments, an adhesive 614 such as epoxy resin may be employed to attach the stiffener 612 to substrate 604. The adhesive cure time may be accelerated using heat, ultraviolet light, accelerant chemicals, or other such means, and the substrate and stiffener may be held in alignment while the adhesive cures. In one such example, the stiffener 612 is attached to the substrate 604 with epoxy before the integrated circuit assembly is mounted to the printed circuit board, such as using a solder reflow process for a ball grid array of electrical contacts 608. In such examples, the standoffs 618 may help ensure that a desired space between the integrated circuit assembly's substrate 604 and the printed circuit board 620 is maintained during mounting or reflow. In an alternate example, the standoff 618 coupled to the protruding portion 616 of the stiffener may help align the stiffener during adhesive cure, such as where the stiffener is added after the integrated circuit assembly's substrate 604 is mounted to the printed circuit board 620 or where the standoff 618 engages another element of the assembly such as substrate 604.

The substrate and the stiffener may be pressed or clamped together during adhesive cure to flatten the integrated circuit assembly, or to set a desired profile in the cured assembly. In one such example, the stiffener and substrate may be held in a direction opposite a known likely direction of deflection of the substrate during adhesive cure to offset or bias the cured integrated circuit assembly in a direction opposite the direction of likely deflection. This may limit the overall range of deflection experienced by the integrated circuit assembly, such as due to differences in coefficients of thermal expansion during reflow to mount the integrated circuit die 602 to the substrate 604 or to mount the substrate to the printed circuit board 620.

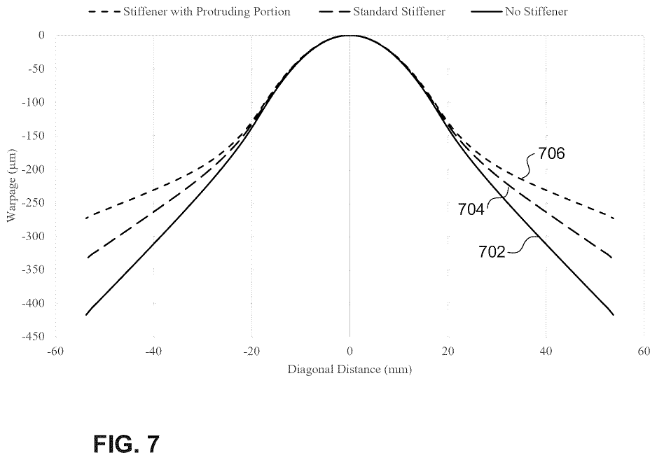

FIG. 7 is a chart showing deflection of various integrated circuit assemblies, consistent with an example embodiment. Here, deflection of a substrate in micrometers as represented on the Y axis is measured diagonally toward corners of a square substrate at a distance from the center of the integrated circuit assembly as represented in millimeters on the X axis.

At 702, the deflection of a substrate of an integrated circuit assembly is shown. The curve illustrates that the corners of the substrate deflect downward as much as 420 micrometers relative to the center of the substrate (typically under the center of the integrated circuit die as shown in the preceding examples). The coefficient of thermal expansion of silicon, a typical material for integrated circuit dies, is about 2.6×10⁻⁶ per degree Celsius, while a typical substrate may have a coefficient of approximately 15×10⁻⁶ per degree Celsius. Because the substrate expands more than the integrated circuit die during reflow and contracts more as the soldered integrated circuit die and substrate cool, the substrate ends up slightly warped as a result of the elevated temperature and the coefficient of thermal expansion mismatch when bonding the integrated circuit die to the substrate.

A typical stiffener with no protruding portions may improve the measured warpage of the substrate significantly, as is shown at 704, where the substrate warps in a negative deflection to approximately 330 micrometers near the edges of the die. While this is better than the 420 micrometer range of deflection of the integrated circuit package with no stiffener, the total warpage or deflection in the substrate is still significant. Incorporating a protruding portion onto the stiffener as shown in FIG. 2 results in the deflection profile shown at 706, in which the total deflection is reduced to about 270 micrometers near the edges of the integrated circuit die, which is a similar improvement over a stiffener with no protruding portion (approximately 20% reduction) as the improvement in deflection range seen by adding a stiffener with no protruding portion to the bare integrated circuit assembly's substrate with no stiffener.

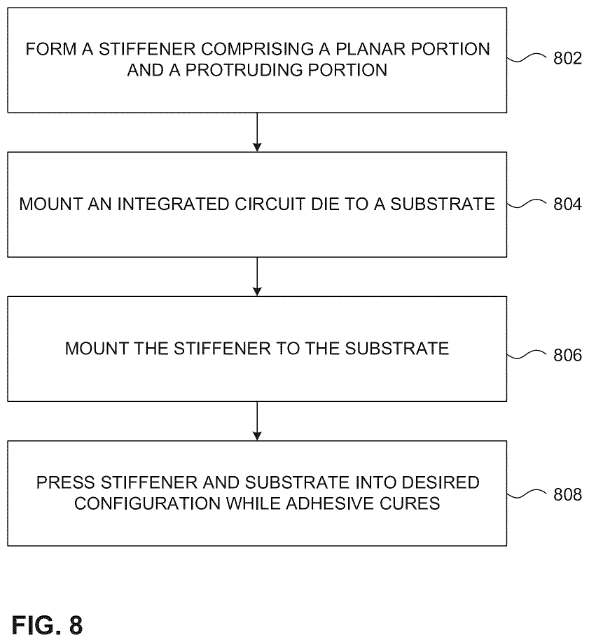

FIG. 8 is a flow diagram of a method of forming an integrated circuit assembly having a stiffener with a protruding portion, consistent with an example embodiment. A stiffener is formed at 802, including both a planar portion for mounting to a planar surface of an integrated circuit package substrate and a protruding portion extending away from the plane of the planar portion of the stiffener. In a further example, the protruding portion may be approximately at a right angle to the planar portion of the stiffener, and/or in a direction of anticipated deflection of the substrate. The stiffener may comprise a metal, ceramic, composite, or other suitable material, such as copper, steel, silicon carbide, aluminum silicon carbide, or the like. The stiffener may be work-hardened to improve its stiffness, such as by bending, drawing, forging, or otherwise manipulating a metal used to form the stiffener.

An integrated circuit die is mounted to the substrate at 808. The integrated circuit die in a more detailed example is mounted to the substrate using a flip chip ball grid array, in which an array or grid of electrical contacts on the integrated circuit are coupled to corresponding electrical contacts on the substrate by reflowing solder balls deposited on the integrated circuit die and/or the substrate using heat, such as in a reflow oven. When the integrated circuit die and substrate are cooled, the relatively high coefficient of thermal expansion of the substrate relative to the integrated circuit die may cause the substrate to warp, which may be resisted by the stiffener.

The stiffener is mounted to the substrate at 806, such as using an epoxy or other adhesive, mechanical fastener, or other suitable attachment means to affix the stiffener to the substrate. The stiffener and the substrate in a further example may be pressed during adhesion as shown at 808, such as to flatten the substrate and stiffener during cure or to pre-stress or warp the substrate and stiffener assembly in an opposite direction of anticipated deflection during use. The adhesive may be cured by heat, ultraviolet light, chemical accelerant, or other accelerated means in some embodiments to aid in setting or fixing a desired profile into the attached stiffener and substrate. In alternate examples, the stiffener may be mounted to the substrate before the integrated circuit die is mounted to the substrate using a reflow process, but the reflow heating process may weaken some epoxy bonds between the stiffener and the substrate.

The examples presented herein illustrate how a stiffener having a planar part for attachment to a planar surface of a substrate and a protruding part extending away from the planar part of the stiffener may provide greater stiffness than a traditional integrated circuit substrate stiffener. The stiffener may be work-hardened in some examples by deforming a metal material used to form the stiffener, such as by drawing, bending, or forging the metal material into the desired stiffener shape or profile. Such a stiffener may significantly reduce the overall deflection observed across an integrated circuit package substrate, reducing potential stress on various packaging or electronic components mounted to the substrate and on the substrate itself.

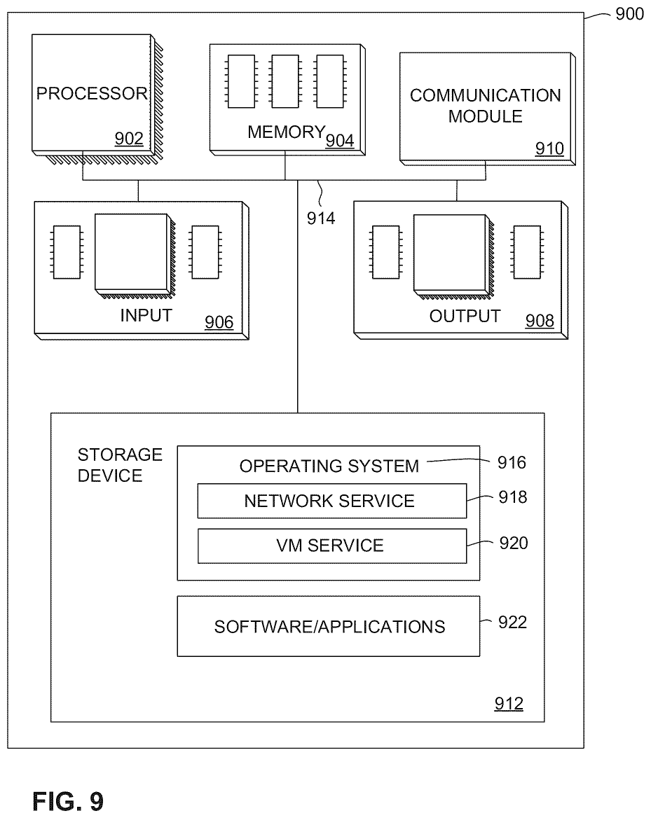

FIG. 9 shows a block diagram of a general-purpose computerized system, consistent with an example embodiment. FIG. 9 illustrates only one particular example of computing device 900, and other computing devices 900 may be used in other embodiments. Although computing device 900 is shown as a standalone computing device, computing device 900 may be any component or system that includes one or more processors or another suitable computing environment for executing software instructions in other examples, and need not include all of the elements shown here.

As shown in the specific example of FIG. 9, computing device 900 includes one or more processors 902, memory 904, one or more input devices 906, one or more output devices 808, one or more communication modules 910, and one or more storage devices 912. Computing device 900, in one example, further includes an operating system 916 executable by computing device 900. The operating system includes in various examples services such as a network service 918 and a virtual machine service 920 such as a virtual server. One or more applications, such as application 922 are also stored on storage device 912, and are executable by computing device 900.

Each of components 902, 904, 906, 908, 910, and 912 may be interconnected (physically, communicatively, and/or operatively) for inter-component communications, such as via one or more communications channels 914. In some examples, communication channels 914 include a system bus, network connection, inter-processor communication network, or any other channel for communicating data. Applications such as software application 922 and operating system 916 may also communicate information with one another as well as with other components in computing device 900.

Processors 902, in one example, are configured to implement functionality and/or process instructions for execution within computing device 900. For example, processors 902 may be capable of processing instructions stored in storage device 912 or memory 904. Examples of processors 902 include any one or more of a microprocessor, a controller, a central processing unit (CPU), a graphics processing unit (GPU), a neural processing unit (NPU), an image signal processor (ISP), a digital signal processor (DSP), an application specific integrated circuit (ASIC), a field-programmable gate array (FPGA), or similar discrete or integrated logic circuitry.

One or more storage devices 912 may be configured to store information within computing device 900 during operation. Storage device 912, in some examples, is known as a computer-readable storage medium. In some examples, storage device 912 comprises temporary memory, meaning that a primary purpose of storage device 912 is not long-term storage. Storage device 9912 in some examples is a volatile memory, meaning that storage device 912 does not maintain stored contents when computing device 900 is turned off. In other examples, data is loaded from storage device 912 into memory 904 during operation. Examples of volatile memories include random access memories (RAM), dynamic random access memories (DRAM), static random access memories (SRAM), and other forms of volatile memories known in the art. In some examples, storage device 912 is used to store program instructions for execution by processors 902. Storage device 912 and memory 904, in various examples, are used by software or applications running on computing device 900 such as software application 922 to temporarily store information during program execution.

Storage device 912, in some examples, includes one or more computer-readable storage media that may be configured to store larger amounts of information than volatile memory. Storage device 912 may further be configured for long-term storage of information. In some examples, storage devices 912 include non-volatile storage elements. Examples of such non-volatile storage elements include magnetic hard discs, optical discs, floppy discs, flash memories, or forms of electrically programmable memories (EPROM) or electrically erasable and programmable (EEPROM) memories.

Computing device 900, in some examples, also includes one or more communication modules 910. Computing device 900 in one example uses communication module 910 to communicate with external devices via one or more networks, such as one or more wireless networks. Communication module 910 may be a network interface card, such as an Ethernet card, an optical transceiver, a radio frequency transceiver, or any other type of device that can send and/or receive information. Other examples of such network interfaces include Bluetooth, 4G, LTE, or 5G, WiFi radios, and Near-Field Communications (NFC), and Universal Serial Bus (USB). In some examples, computing device 900 uses communication module 910 to wirelessly communicate with an external device such as via a public network.

Computing device 900 also includes in one example one or more input devices 906. Input device 906, in some examples, is configured to receive input from a user through tactile, audio, or video input. Examples of input device 906 include a touchscreen display, a mouse, a keyboard, a voice responsive system, video camera, microphone or any other type of device for detecting input from a user.

One or more output devices 908 may also be included in computing device 900. Output device 908, in some examples, is configured to provide output to a user using tactile, audio, or video stimuli. Output device 908, in one example, includes a display, a sound card, a video graphics adapter card, or any other type of device for converting a signal into an appropriate form understandable to humans or machines. Additional examples of output device 908 include a speaker, a light-emitting diode (LED) display, a liquid crystal display (LCD or OLED), or any other type of device that can generate output to a user.

Computing device 900 may include operating system 916. Operating system 916, in some examples, controls the operation of components of computing device 900, and provides an interface from various applications such as software application 922 to components of computing device 900. For example, operating system 916, in one example, facilitates the communication of various applications such as software application 922 with processors 902, communication unit 910, storage device 912, input device 906, and output device 908. Applications such as application 922 may include program instructions and/or data that are executable by computing device 900. These and other program instructions or modules may include instructions that cause computing device 900 to perform one or more of the other operations and actions described in the examples presented herein.

Process cores, bitcell arrays, memory structures, peripheral circuitry, and other circuits as described herein in particular examples may be formed in whole or in part by and/or expressed in transistors and/or lower metal interconnects (not shown) in processes (e.g., front end-of-line and/or back-end-of-line processes) such as processes to form complementary metal oxide semiconductor (CMOS) circuitry. The various blocks, neural networks, and other elements disclosed herein may be described using computer aided design tools and expressed (or represented), as data and/or instructions embodied in various computer-readable media, in terms of their behavioral, register transfer, logic component, transistor, layout geometries, and/or other characteristics.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioral representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Features of example computing devices employed in example embodiments may comprise features, for example, of a client computing device and/or a server computing device. The term computing device, in general, whether employed as a client and/or as a server, or otherwise, refers at least to a processor and a memory connected by a communication bus. A “processor” and/or “processing circuit” for example, is understood to connote a specific structure such as a central processing unit (CPU), digital signal processor (DSP), graphics processing unit (GPU), image signal processor (ISP) and/or neural processing unit (NPU), or a combination thereof, of a computing device which may include a control unit and an execution unit. In an aspect, a processor and/or processing circuit may comprise a device that fetches, interprets and executes instructions to process input signals to provide output signals. As such, in the context of the present patent application at least, this is understood to refer to sufficient structure within the meaning of 35 USC § 112 (f) so that it is specifically intended that 35 USC § 112 (f) not be implicated by use of the term “computing device,” “processor,” “processing unit,” “processing circuit” and/or similar terms; however, if it is determined, for some reason not immediately apparent, that the foregoing understanding cannot stand and that 35 USC § 112 (f), therefore, necessarily is implicated by the use of the term “computing device” and/or similar terms, then, it is intended, pursuant to that statutory section, that corresponding structure, material and/or acts for performing one or more functions be understood and be interpreted to be described at least in FIG. 1 and in the text associated with the foregoing figure(s) of the present patent application.

Some embodiments may be described, at least in part, by the following numbered clauses or by any combination thereof:

Clause 1: An assembly, comprising: a substrate; an integrated circuit die physically and electrically attached to the substrate; and a stiffener attached to the substrate, the stiffener comprising a planar portion and a protruding portion, the planar portion to be attached to the substrate and to be positioned approximately parallel to a planar surface of the substrate, the protruding portion to extend away from the planar portion of the stiffener.

Clause 2: The assembly of clause 1, wherein the protruding portion of the stiffener is approximately perpendicular to the planar portion of the stiffener.

Clause 3: The assembly of any of the aforementioned clauses, wherein the stiffener comprises copper, steel, silicon carbide or aluminum silicon carbide, or a combination thereof.

Clause 4: The assembly of any of the aforementioned clauses, wherein the protruding portion of the stiffener extends away from the substrate and is confined within edges of the planar surface of the substrate.

Clause 5: The assembly of any of the aforementioned clauses, wherein the planar portion of the stiffener extends approximately a same height from the substrate as a side of the integrated circuit die opposite the substrate.

Clause 6: The assembly of clause 5, further comprising a thermal bonding material applied to the side of the integrated circuit die opposite the substrate.

Clause 7: The assembly of any of the aforementioned clauses, further comprising a heat sink coupled to a side of the integrated circuit die opposite the substrate.

Clause 8: The assembly of any of the aforementioned clauses, further comprising a standoff coupled to the protruding portion, the standoff configured to maintain space between the substrate and a printed circuit board attachable to the substrate.

Clause 9: The assembly of any of the aforementioned clauses, wherein the stiffener comprises one or more bends to impart stiffness through work hardening of the stiffener.

Clause 10:10.The assembly of any of the aforementioned clauses, further comprising an epoxy adhesive to attach the planar portion of the stiffener to the substrate.

Clause 11: The assembly of clause 10, the epoxy adhesive further to hold the planar portion of the stiffener and the substrate together in a flattened position.

Clause 12: A method of forming an assembly, comprising: mounting an integrated circuit die to a substrate; forming a stiffener comprising a planar portion and a protruding portion; and mounting the stiffener to the substrate, the planar portion of the stiffener mounted approximately parallel to a planar surface of the substrate, the protruding portion to extend away from the planar portion of the stiffener.

Clause 13: The method of forming an assembly of claim 12, wherein the protruding portion of the stiffener is approximately perpendicular to the planar portion of the stiffener.

Clause 14: The method of forming an assembly of any of clauses 12-13, wherein the stiffener comprises copper, steel, silicon carbide or aluminum silicon carbide, or a combination thereof.

Clause 15: The method of forming an assembly of any of clauses 12-14, further comprising applying a thermal interface material to a side of the integrated circuit die opposite the substrate.

Clause 16: The method of forming an assembly of clause 15, further comprising mounting a heat sink to the side of the integrated circuit die opposite the substrate in contact with the thermal interface material.

Clause 17: The method of forming an assembly of any of clauses 12-16, further comprising forming a standoff coupled to the protruding portion, the standoff configured to maintain a space between the substrate and a printed circuit board to be attachable the substrate.

Clause 18: The method of forming an assembly of any of clauses 12-17, wherein mounting the stiffener to the substrate comprises applying an epoxy adhesive to attach the planar portion of the stiffener to the substrate, and pressing the planar portion of the stiffener and the substrate during epoxy adhesion to flatten the substrate.

Clause 19: An assembly, comprising: a stiffener configured to attach to a substrate carrying an integrated circuit die, the stiffener comprising a work hardened material, the stiffener comprising a planar portion in a plane approximately parallel to a plane of the substrate when attached to the substrate, and a protruding portion extending away from the plane of the planar portion of the stiffener.

Clause 20: The assembly of clause 19, wherein the work hardened material comprises a material work hardened by bending, forging, or drawing, or a combination thereof, at least a portion of the stiffener.

Although specific embodiments have been illustrated and described herein, any arrangement that achieve the same purpose, structure, or function may be substituted for the specific embodiments shown. This application is intended to cover any adaptations or variations of the example embodiments of the invention described herein. These and other embodiments are within the scope of the following claims and their equivalents.

What is claimed is:

1. An assembly, comprising:
a substrate;
an integrated circuit die physically and electrically attached to the substrate; and
a stiffener attached to the substrate, the stiffener comprising a planar portion and a protruding portion, the stiffener leaving at least a portion of the integrated circuit die exposed, the planar portion to be attached to the substrate and to be positioned approximately parallel to a planar surface of the substrate, the protruding portion to extend away from the planar portion of the stiffener.

2. The assembly of claim 1, wherein the protruding portion of the stiffener is approximately perpendicular to the planar portion of the stiffener.

3. The assembly of claim 1, wherein the stiffener comprises copper, steel, silicon carbide or aluminum silicon carbide, or a combination thereof.

4. The assembly of claim 1, wherein the protruding portion of the stiffener extends away from the substrate and is confined within edges of the planar surface of the substrate.

5. The assembly of claim 1, wherein the protruding portion of the stiffener extends past an edge of the planar surface of the substrate.

6. The assembly of claim 1, wherein the planar portion of the stiffener extends approximately a same height from the substrate as a side of the integrated circuit die opposite the substrate.

7. The assembly of claim 6, further comprising a thermal bonding material applied to the side of the integrated circuit die opposite the substrate.

8. The assembly of claim 1, further comprising a heat sink coupled to a side of the integrated circuit die opposite the substrate.

9. The assembly of claim 1, further comprising a standoff coupled to the protruding portion, the standoff configured to maintain space between the substrate and a printed circuit board attachable to the substrate.

10. The assembly of claim 1, wherein the stiffener comprises one or more bends to impart stiffness through work hardening of the stiffener.

11. The assembly of claim 1, the protruding portion to extend away from the planar portion of the stiffener in both directions from the planar portion of the stiffener.

12. The assembly of claim 11, further comprising an adhesive to attach the planar portion of the stiffener to the substrate, the adhesive further to hold the planar portion of the stiffener and the substrate together in a flattened position.

13. A method of forming an assembly, comprising:
mounting an integrated circuit die to a substrate;
forming a stiffener comprising a planar portion and a protruding portion; and
mounting the stiffener to the substrate, the stiffener leaving at least a portion of the integrated circuit die exposed, the planar portion of the stiffener mounted approximately parallel to a planar surface of the substrate, the protruding portion to extend away from the planar portion of the stiffener.

14. The method of forming an assembly of claim 13, wherein the protruding portion of the stiffener is approximately perpendicular to the planar portion of the stiffener.

15. The method of forming an assembly of claim 13, further comprising applying a thermal interface material to a side of the integrated circuit die opposite the substrate.

16. The method of forming an assembly of claim 15, further comprising mounting a heat sink to the side of the integrated circuit die opposite the substrate in contact with the thermal interface material.

17. The method of forming an assembly of claim 13, further comprising forming a standoff coupled to the protruding portion, the standoff configured to maintain a space between the substrate and a printed circuit board to be attachable the substrate.

18. The method of forming an assembly of claim 13, wherein mounting the stiffener to the substrate comprises applying an adhesive to attach the planar portion of the stiffener to the substrate, and pressing the planar portion of the stiffener and the substrate during epoxy adhesion to flatten the substrate.

19. An assembly, comprising:
a stiffener configured to attach to a substrate carrying an integrated circuit die, the stiffener comprising a work-hardened material, the stiffener comprising a planar portion in a plane approximately parallel to a plane of the substrate when attached to the substrate, and a protruding portion extending away from the plane of the planar portion of the stiffener.

20. The assembly of claim 19, wherein the work-hardened material comprises a material work-hardened by bending, forging, or drawing, or a combination thereof, at least a portion of the stiffener.
